(19) United States
(12) Patent Application Publication
(10) Pub. No.: US 2012/0127687 A1
(43) Pub. Date: May 24, 2012

(54) FLEXIBLE CIRCUITS AND ELECTRONIC TEXTILES

(75) Inventors: David R. Allee, Phoenix, AZ (US); Bruce Gnade, Lewisville, TX (US)

(73) Assignees: Arizona Board of Regents, a body corporate of the State of Arizona, Acting for and on behalf of; Board of Regents, the University of Texas System, Austin, TX (US); Arizona State University, Scottsdale, AZ (US)

(21) Appl. No.: 13/349,820

(22) Filed: Jan. 13, 2012

Related U.S. Application Data
(63) Continuation of application No. PCT/US2010/034978, filed on May 14, 2010.
(60) Provisional application No. 61/225,156, filed on Jul. 13, 2009.
(60) Provisional application No. 61/235,270, filed on Aug. 19, 2009.
(60) Provisional application No. 61/265,443, filed on Dec. 1, 2009.

(51) Int. Cl. H05K 7/02; D03D 15/00; D03D 41/00

(52) U.S. Cl. 361/807; 139/11; 139/425 R

(57) ABSTRACT

Embodiments of wearable flexible devices and related methods are described herein. Other embodiments and related methods are also disclosed herein.

### CROSS REFERENCE TO RELATED APPLICATIONS

This patent application is a continuation of International (PCT) Patent Application No. PCT/US2010/034978, filed on May 14, 2010, which aims priority to U.S. Provisional Patent Application 61/225,156, filed on Jul. 13, 2009, U.S. Provisional Patent Application 61/235,270, filed on Aug. 19, 2009, and U.S. Provisional Patent Application 61/265,443, filed on Dec. 1, 2009. The contents of the applications identified above are incorporated herein by reference.

### STATEMENT REGARDING FEDERAL GOVERNMENT SPONSORSHIP

At least part of the disclosure herein was funded with government support under grant number W911NF-04-2-0005, awarded by the Army Research Laboratory. The United States Government may have certain rights in this invention.

### FIELD OF THE INVENTION

The present invention relates generally to flexible circuits. More particularly the present invention relates to wearable flexible circuits, electronic textiles, and related methods.

### BACKGROUND

Development of electronic textiles, such as those incorporating electronic circuitry with fibers of cloth, has become of great interest. One goal is to create electrically active fabric that can breathe and stretch like clothing, yet can perform computation, sensing, and/or image display functions.

One problem with current approaches involves the electrical connection between horizontal and vertical fibers, where the connection between fibers essentially fixes the relative position of the fibers, thereby preventing them from sliding past one another. The problem is especially severe for flexible, textile displays where thousands or millions of connections must be made. A connection must be made between every row (horizontal fiber) and column (vertical fiber) of the display. These connections are essential to update the image In a traditional display, data is passed down all columns simultaneously while one row at a time is activated to load the data into a row of pixels. Because there is a rigid connection between every row and column connection, the resulting textile displays have been quite rigid, and thus do not stretch or breathe similar to non-electronic textiles.

### BRIEF DESCRIPTION OF THE DRAWINGS

To facilitate further description of the embodiments, the following drawings are provided in which:

FIG. 1 is an illustration of an exemplary flexible device according to an embodiment;

FIG. 2 is an illustration of another example of the flexible device of the embodiment of FIG. 1;

FIG. 3 is an example of a zoomed-in portion of the flexible device of FIG. 1;

FIG. 4 is another example of a zoomed-in portion of the flexible device of FIG. 1;

FIG. 5 is another example of a zoomed-in portion of the flexible device of FIG. 1;

FIG. 6 is another example of a zoomed-in portion of the flexible device of FIG. 1; and

FIG. 7 is a flow chart illustrating an exemplary method of providing a flexible device according to an embodiment.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein.

The terms “couple,” “coupled,” “couples,” “coupling,” and the like should be broadly understood and refer to connecting two or more elements or signals, electrically, mechanically and/or otherwise. Two or more electrical elements may be electrically coupled together but not be mechanically or otherwise coupled together; two or more mechanical elements may be mechanically coupled together, but not be electrically or otherwise coupled together; two or more electrical elements may be mechanically coupled together, but not be electrically or otherwise coupled together. Coupling may be for any length of time, e.g., permanent or semi-permanent or only for an instant.

An electrical “coupling” and the like should be broadly understood and include coupling involving any electrical signal, whether a power signal, a data signal, and/or other types or combinations of electrical signals. A mechanical “coupling” and the like should be broadly understood and include mechanical coupling of all types. The absence of the word “removably,” “removable,” and the like near the word “coupled,” and the like does not mean that the coupling, etc. in question is or is not removable.

### DETAILED DESCRIPTION

In some embodiments, a flexible device can comprise flexible strips, wherein the flexible strips comprise electrical components and at least one shift register. There can also be embodiments where a flexible device can include: fibers arranged in rows and columns, where the rows of fibers are interwoven with the columns of fibers, where at least a portion of the fibers include flexible strips, where each of the flexible strips include at least one electrical component, and where the rows of fibers are not electrically coupled to the columns of fibers.

In yet other embodiments, a method for providing a flexible device can include: providing a row of fibers; providing a column of fibers; and interweaving the rows of fibers and the columns of fibers, where at least a portion of the fibers include flexible strips having at least one electrical component.

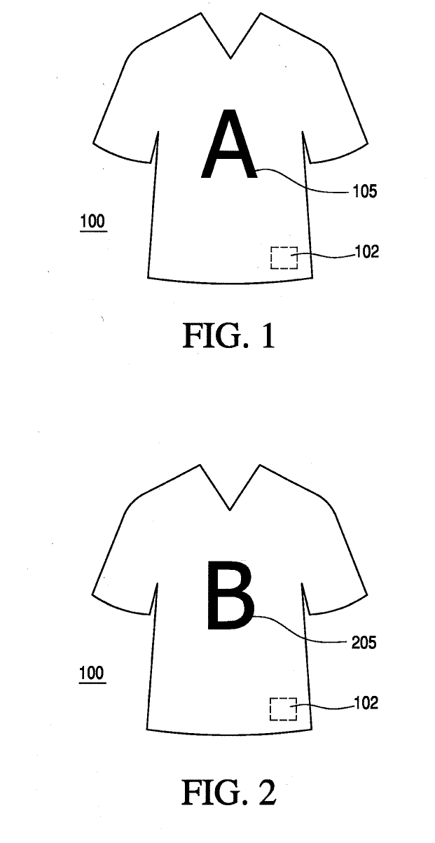

Turning to the drawings, FIG. 1 illustrates an example of a flexible device 100, according to one embodiment. In the same or different embodiments, method 100 can be a wearable flexible display. Device 100 can also be considered a textile fabric with display properties. Device 100 is merely exemplary and is not limited to the embodiments presented herein. Device 100 can be employed in many different embodiments or examples not specifically depicted or described herein.

As can be seen in FIG. 1, device 100 can be in the form of a shirt to be worn by a user. In other examples, device 100 can comprise other types of garments. For example, device 100 can comprise a pair of pants, a pair of shorts, a jacket, a sweater, a hat, or any other type of garment than can be worn. Device 100 can also be only a portion of such a garment. In addition, device 100 can comprise other items that are not configured to be worn, but are commonly made with textiles. An example of one such item is a blanket.

Device 100 can display an image 105. For example, as seen in FIG. 1, image 105 can comprise the letter “A.” It should be noted that image 105 can be any image imaginable. In addition, the image displayed on device 100 can be altered or changed entirely. As an example, FIG. 2 shows device 100 with a second image 205. Second image 205 in the example of FIG. 2 comprises the letter “B.”

In yet other examples, multiple images can be displayed at different times on device 100. For example, device 100 can alternate between two images, such as, for example, image 105 (FIG. 1) and image 205 (FIG. 2) In another example, device 100 can comprise 10 distinct images that are to be displayed on device 100. Each of the images can be displayed for a preset period of time, and then, the next image can be displayed. Any number of images can be displayed by device 100. In further examples, device 100 can display video images, scenery, a random pattern, or another pattern.

In some embodiments, substantially or entirely all of device 100 can display an image. For example, if device 100 comprises a shirt, the entire surface area of the shirt can display and image. In other embodiments, only a portion of device 100 can display an image. For example, if device 100 comprises a shirt, only a portion on the front of the shirt can display an image.

In another embodiment, device 100 can comprise a detection system. The detection system can be used to detect substances in the environment surrounding device 100. As an example, device 100 can vibrate, sound an alarm, give visual cues, or provide a slight shock to the user when a dangerous substance is present in the environment surrounding device 100. Examples of substances that can be detected by device 100 can include visible light, x-rays, gamma rays, neutrons, protons, infrared light, chemicals, and the like. In some embodiments, device 100 can display an image and comprise a detection system.

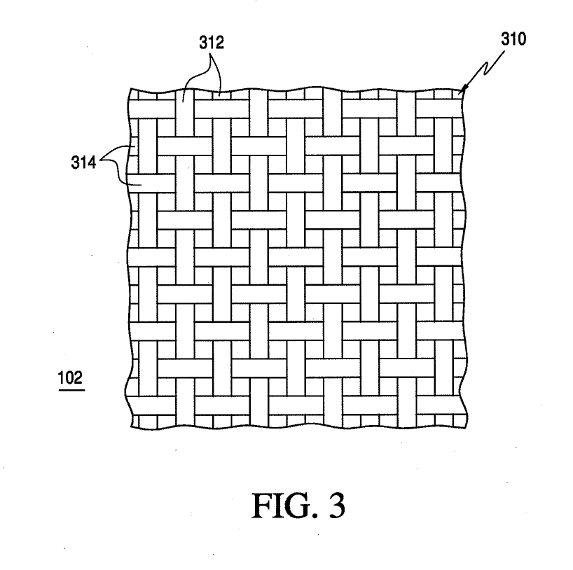

Device 100 comprises fibers. The fibers of device 100 are interwoven with one another. In some examples, the fibers are arranged in rows and columns. The rows and columns are then interwoven together. FIG. 3 is a zoomed-in illustration of an example of a portion 102 of device 100 of FIGS. 1 and 2. Although portion 102 appears as just a portion of device 100, portion 102 can be representative of the entirety of device 100. In other embodiments, portion 102 is all of device 100, which is only a portion of a garment. Portion 102 is merely exemplary and is not limited to the embodiments presented herein. Portion 102 can be employed in many different embodiments or examples not specifically depicted or described herein.

Portion 102 comprises fibers 310 arranged in columns 312 and rows 314. Also, as seen in FIG. 3, columns 312 and rows 314 are interwoven. It should also be noted that fibers 310 do not have to be arranged in rows and columns, but can exist in other arrangements, such as, for example, any arrangement or pattern in which fibers, such as textile threads, are used to make textile fabrics.

Fibers 310 that are present in device 100 can comprise different types of materials. For example, fibers 310 can include textile threads. Textile threads can include threads that are traditionally used to make garments. Examples of such threads can include, for example, threads made of cotton, wool, silk, synthetic fibers, etc. In addition, textile threads can include other materials that may have additional benefits. For example, textile threads can include Kevlar® threads. In some examples, the textile threads can be approximately 0.10 millimeters (mm) or 0.2 mm thick. In other examples, the textile threads can be greater than approximately 0.10 mm or 0.2 mm. In yet other examples, the textile threads can be less than approximately 0.10 mm or 0.2 mm.

In addition, fibers 310 can include flexible strips. The flexible strips comprise active components such as one or more semiconductor and/or other devices. As a result, the flexible strips can be fibers of material that have functional components. For example, the flexible strips can include pixels that give off light to produce an image. In the same or other examples, the flexible strips can included sensors to detect substances, radiation, etc. In some examples, the flexible strips are approximately 1 mm in width. In other examples, the flexible strips can be approximately 0.50 mm in width. In yet other examples, the flexible strips can be greater than approximately 1 mm, between approximately 1 mm and approximately 0.50 mm, or less than approximately 0.50 mm in width. The length of the flexible strips can vary depending on the length needed for the functional components of the flexible strips and/or the length needed to create flexible device 100.

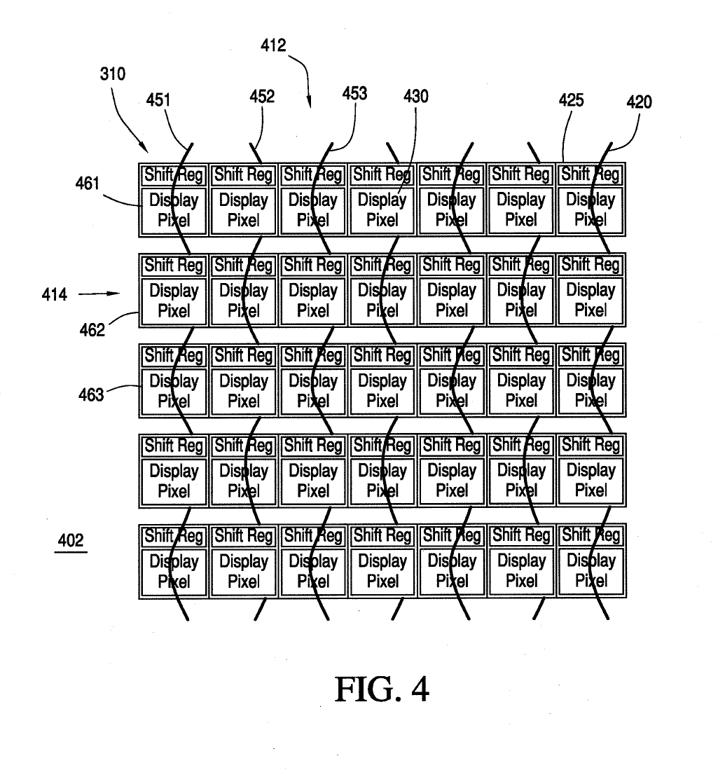

FIG. 4 illustrates another example of a portion 402 of device 100. Portion 402 is merely exemplary and is not limited to the embodiments presented herein. Portion 402 can be employed in many different embodiments or examples not specifically depicted or described herein. Portion 402 can be similar to portion 102 (FIG. 3). Portion 402 can be representative of a portion of device 100 or representative of the entirety of device 100. Portion 402 comprises fibers 310. Fibers 310 are arranged into rows 414 and columns 412. As can be seen in FIG. 4, rows 414 comprise flexible strips 425, and columns 412 comprise textile threads 420. In another example (not shown), rows 414 can comprise textile threads 420, and columns 412 can comprise flexible strips 425.

Flexible strips 425 can comprise electrical components 430. Electrical components 430 are functional aspects of device 100. For example, electrical components 430 can be reflecting or emitting pixels. Flexible strips 425 can be individual display or elements connected in series to form the shape of a long strip, where each flexible strip 425 forms one row (or column) of device 100 as a horizontal (or vertical) sequence of display pixels. Each of the pixels can be configured to be a source of light. As an example, each pixel can be configured to be in an “on” state, where the pixel is giving off a light, or can be in an “off” state, where no light is being given off. Flexible strips 425 can include pixels of many different types of display devices. For example, the pixels can be for an emissive or reflective display. In addition, the pixels may be part of a bistable display. A bistable display is one in which no power is needed to uphold the image of the display. The use of a bistable display is advantageous in that less power is needed to operate the display device. Examples of bistable displays can include liquid crystal displays (LCD), electrophoretic displays, and electrochromic displays. Displays that aren't bistable require a greater amount of power to operate because a bias needs to be constantly applied to the pixels for the pixels to emit/reflect light.

The combination of all the pixels of device 100 emitting a light can produce an image, such as, for example, images 105 and/or 205 (FIGS. 1 and 2). In some examples, the pixels are configured to emit a white tone. In other examples, the pixels can emit colors, such as, for example, red, green, and blue (RGB) tones, thus allowing the image displayed by device 100 to be in color. The size and the number of pixels on the flexible strips can be adjusted to alter the resolution of device 100. In some examples, the pixels are approximately 0.20 mm in width. In other examples, the pixels are approximately 0.10 mm in width. In further examples, the pixels can be approximately 0.05 mm in width. As the size of the pixel, decreases the cost of the pixels can increase. In addition, the durability and/or reliability of the pixels may decrease as the size of the pixels decreases. Therefore, it may be necessary to balance a higher resolution with cost/durability issues when determining the size of the pixels.

Flexible strips 425 can also comprise shift registers. Each of flexible strips 425 can include at least one shift register. Data can be sent to and updated in each strip by shifting the data along the strip with the shift register. The use of shift registers allow data to be sent along the row (or column) of that particular flexible strip. Therefore, there is no need to have the rows and columns electrically coupled at every location of a pixel or at every location adjacent to a pixel. Having such electrical couplings of the rows and columns can create a device that is very stiff and inflexible, thus making the device nearly impossible to wear as a garment.

In some examples, the shift register is a flexible complementary metal oxide semiconductor (CMOS) shift register. Flexible CMOS has a low power consumption, which helps flexible strips 425 to be configured in a way that the flexible strips can be worn as a garment or similar device. In addition, the flexible CMOS shift registers can be built relatively small, allowing a higher percentage of the area of flexible strips 425 to be used for pixels, which can create a higher resolution on device 100 than if a lower percentage of the area of flexible strips 425 are used for pixels. In other examples, p-type channel metal oxide semiconductor (PMOS) and/or n-type channel metal oxide semiconductor (NMOS) shift registers can be used.

In some examples, flexible strips 425 can produce more than one image for device 100. For example, the combination of pixels on flexible strips 425 can produce a first image, such as, for example image 105 (FIG. 1). In addition, flexible strips can be configured to replace the first image with a second image, such as, for example, image 205 (FIG. 2). It is also possible for flexible strips to produce more than 2 images. In some examples, flexible strips 425 can provide video images on device 100. In some examples, the bandwidth of flexible strips is lower than that of a standard television (approximately 60 hertz), and therefore the rate of change in the video/images of device 100 will be slower than that seen on standard televisions.

In some embodiments, device 100 can include additional components. As an example, device 100 can include a battery and/or control unit. When power is needed for device 100, such as, for example, when a PMOS or NMOS shift register is used, or when emissive/reflective displays are used, device 100 can include a battery to power device 100. The battery can also be made of flexible materials similar to or the same as flexible strips 425.

In addition, if images are being changed on device 100, or if video is being displayed on device 100, it may be necessary for device 100 to include a control unit. The control unit can include a central processing unit (CPU) or a microcontroller, which includes a CPU and a memory. The control unit can send instructions to flexible strips 425 for changing images and/or storing multiple images and/or instructions in the memory. The control unit can also be made of flexible materials similar to or the same as flexible strips 425. In addition, device 100 can include a pocket created from fibers 310 to store the battery and/or control unit. In some examples, such as when a bistable display is used with only one image, device 100 will not need a battery or control unit. A control unit and/or power source can be provided that will attach to device 100 to supply and upload the image to device 100 and supply any power necessary to do so.

As can be seen in FIG. 4, each of the rows 414 comprises a flexible strip 425, and each of the columns 412 comprises a textile thread 420. Flexible strips 425 and textile threads are then woven together. As an example, a first textile thread 451 goes over a first flexible strip 461. Then, first textile thread 451 goes under a second flexible strip 462. Subsequently, first textile thread goes over a third flexible strip 463. First textile thread 451 keeps repeating the pattern of over and under for each flexible strip with which it is interwoven.

Opposite of first textile thread 451, a second textile thread 452 goes under first flexible strip 461, over second flexible strip 462, under third flexible strip 463, and so on. Similar to first textile thread 451, a third textile thread 453 goes over first flexible strip 461, under second flexible strip 462, over third flexible strip 463, and so on. The next textile thread in device 100 will be arranged similar to second textile thread 452. Every other textile thread 420 will have the same pattern relative to flexible strips 425. Adjacent textile threads 420 will have the opposite arrangement from one another relative to flexible strips 425.

The arrangement of flexible strips 425 and textile threads 420 allows flexible strips 425 and textile threads 420 to slide with respect to the other. Thus, device 100 is able to be worn similarly to a garment that contains only textile threads, while being able to be used as a display. Also, although textile threads are located over portions of flexible strips 425 and their pixels, the image to be displayed by the pixels is still visible, legible, and/or discernable because textile threads are much narrower than flexible strips 425.

It should be noted that device 100 can contain other arrangements of textile threads 420 and flexible strips 425. As an example, only a portion of rows 414 may contain flexible strips 425. Such an arrangement may be particularly useful if only a portion of device 100 is to be configured with the ability to display an image. In another example, if the resolution of the image is low, rows 414 can include one flexible strip, one or more textile threads, one flexible strip, one or more textile threads, and so on. In other examples, rows 414 and columns 412 may be interwoven in a fashion other than that illustrated in FIGS. 3 and 4.

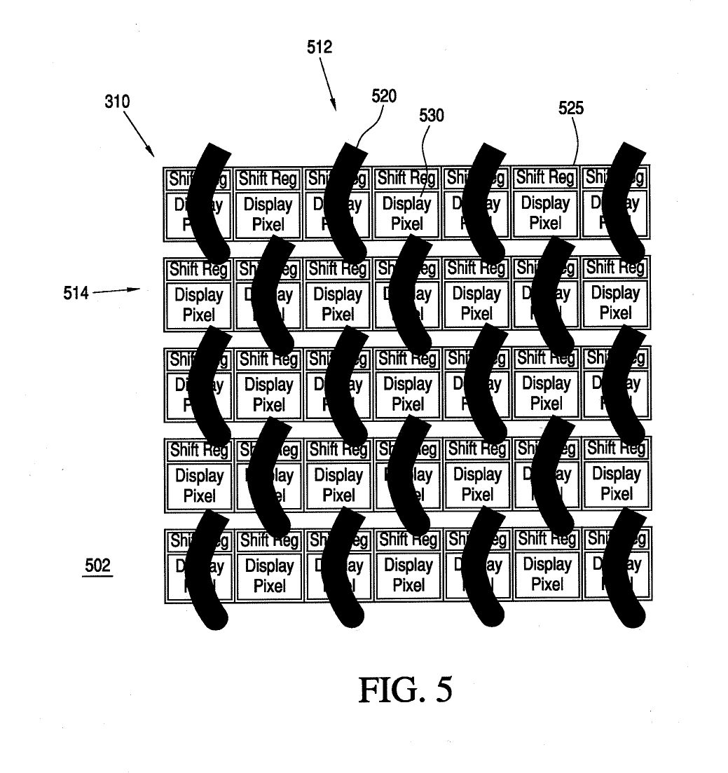

FIG. 5 illustrates another example of a portion 502 of device 100. Portion 502 is merely exemplary and is not limited to the embodiments presented herein. Portion 502 can be employed in many different embodiments or examples not specifically depicted or described herein.

Portion 502 can be similar to portions 102 (FIG. 3) and/or 402 (FIG. 4). Portion 502 comprises fibers 310. Fibers 310 are arranged into rows 514 and columns 512. As can be seen in FIG. 5, rows 514 comprise flexible strips 525, which comprise electrical components 530, and columns 512 comprise textile threads 520. In another example (not shown), rows 514 can comprise textile threads 520, and columns 512 can comprise flexible strips 525. Flexible strips 525 can be similar to flexible strips 425 (FIG. 4). Textile threads 520 can be similar to or the same as textile threads 420 (FIG. 4). Electrical components 530 can be similar to or the same as electrical components 430 (FIG. 4).

In the example illustrated in FIG. 5, the ratio of the width of textile threads 520 to the width of the electrical components 530 is greater that the ratio of the width of textile threads 420 to the width of electrical components 430 of FIG. 4. When electrical components 530 comprise pixels, the resolution of an image produced by device 100 is greatly reduced because every other pixel of device 100 is significantly covered by a textile thread 520. This ratio of the width of textile threads 520 to the width of electrical components 530 can increase when the width of textile threads 520 increase and/or the width of electrical components 530 decrease. Often, the width of electrical components 530 will decrease because smaller pixels are used. Smaller pixels are often used so that more pixels will fit within the space of the device and, therefore, the device will have a greater resolution. This greater resolution, however, will be decreased due to textile threads 520 covering many of the pixels of electrical components 530. As an example, the textile threads can be approximately 0.10 mm in width and the pixels can be approximately 0.10 in width or smaller. Therefore, some pixels may be entirely covered by the textile threads.

In another example, there can be areas between electrical components 530 in which no pixels are present. In such an example, textile threads 520 may pass over flexible strips 525 in the areas in which no pixels are present. Therefore, few pixels, or perhaps no pixels, will be covered by textile threads 520.

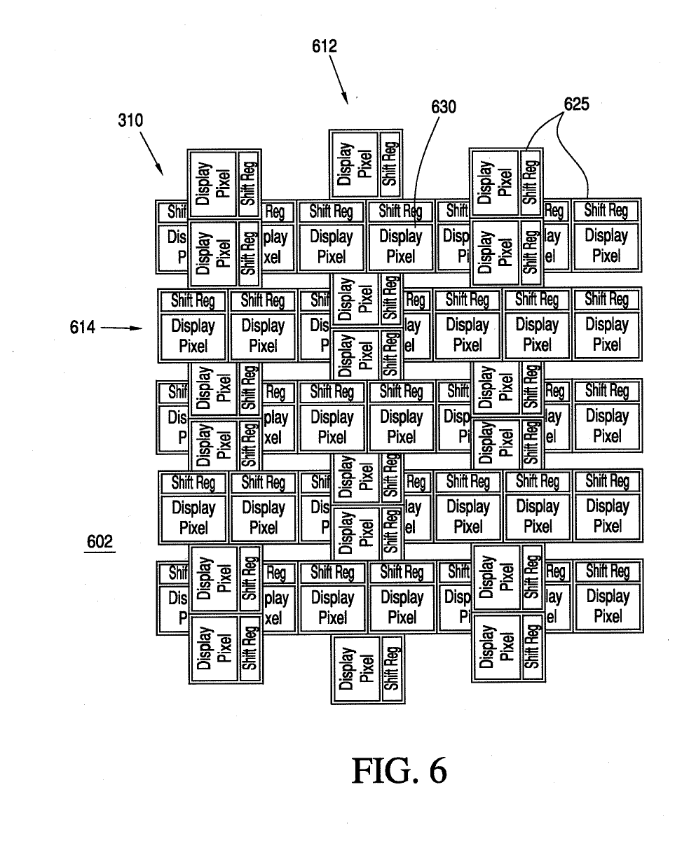

FIG. 6 illustrates another example of a portion 602 of device 100. Portion 602 is merely exemplary and is not limited to the embodiments presented herein. Portion 602 can be employed in many different embodiments or examples not specifically depicted or described herein.

Portion 602 can be similar to portions 102 (FIG. 3), 402 (FIG. 4), and/or 502 (FIG. 5). Portion 602 comprises fibers 310. Fibers 310 are arranged into rows 614 and columns 612. As can be seen in FIG. 6, rows 614 and columns 612 comprise flexible strips 625, which contain electrical components 630. Flexible strips 625 can be similar to flexible strips 425 (FIG. 4) and/or 525 (FIG. 5). Electrical components 630 can be similar to or the same as electrical components 430 (FIG. 4) and/or 530 (FIG. 5).

Similar to the examples of FIGS. 4 and 5, the example of FIG. 6 includes rows 614 and columns 612 that are interwoven. The pattern of the interweaving of rows 614 and columns 612 can be the same as that illustrated in FIGS. 4 and 5. Thus, some of electrical components 630 of flexible strips 625 of rows 614 are covered by flexible strips 625 of columns 612. However, flexible strips 625 of columns 612 also contain electrical components 630. Therefore, in the example of portion 602 of FIG. 6, each time one of electrical components 630 is covered, it is covered by another one of electrical components 630. In such an example, the resolution an image of device 100, which contains portion 602, will be greater than a device with portions 402 (FIG. 4) and/or 502 (FIG. 5).

In addition, portion 602 is arranged similar to portions 402 and 502, in that there is no coupling (electrical or mechanical) or electrical shorting between rows 614 and columns 612. Therefore, flexible strips of rows 614 and columns 612 are able to slide back and forth. This arrangement creates a device that is similar in wearability and feel to a garment made only of textile threads.

It should also be noted that device 100 (FIG. 1) can contain more that one type of fiber arrangement. For example, one area of device 100 can have fibers arranged similar to that of portion 402 of FIG. 4. In addition, a separate area of device 100 can have fibers arranged similar to that of portion 602 of FIG. 6. This configuration allows the designer of device 100 to design device 100 to be able to display one or more particular images at one or more particular resolutions.

As mentioned above, some embodiments of device 100 can contain electrical components, such as, for example, electrical components 430 (FIG. 4), 530 (FIG. 5), and 630 (FIG. 6), that comprise sensors. The sensors can be used to detect the presence of foreign substances, such as, for example, light, x-rays, neutrons, protons, infrared, and/or chemicals. In such an example, if any single sensor of the electrical components detected the foreign substance or substances that the sensor was designed to detect, a signal would be sent to a control unit. The control unit would instruct device 100 to give off a signal, such as, for example, vibrations, visual cues, and/or sounds. In some embodiments, device 100 can include electrical components. Some of the electrical components can include sensors, and other electrical components can include pixels. In other embodiments, the flexible strips of device 100 can comprise electronic circuitry for purposes other the displaying an image or being used as a sensor.

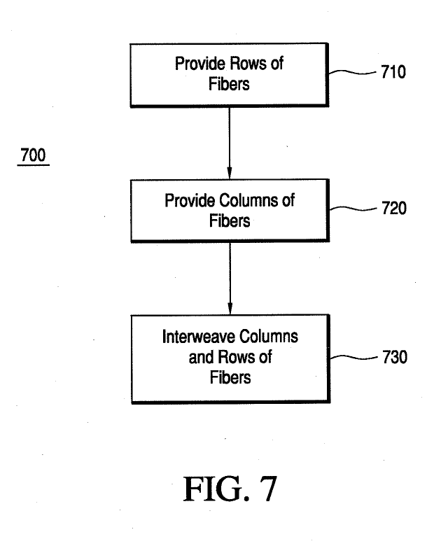

FIG. 7 illustrates an example of a method 700 of providing a flexible device. In some embodiments method 700 can be considered a method of providing a wearable flexible display. In other embodiments method 700 can be considered a method of providing a garment with display capabilities. Method 700 is merely exemplary and is not limited to embodiments presented herein. Method 700 can be implemented in many different embodiments or examples not presented herein.

Method 700 includes a procedure 710 of providing rows of fibers. The fibers can be similar to or the same as fibers 310 (FIGS. 3-6). The rows of fibers also can be similar to or the same as rows 314 (FIG. 3), 414 (FIG. 4), 514 (FIG. 5), and/or 614 (FIG. 6).

In some embodiments, the rows of fibers of procedure 710 comprise flexible strips. The flexible strips can be the same as or similar to flexible strips 425 (FIG. 4), 525 (FIG. 5), and/or 625 (FIG. 6). In some embodiments, the flexible strips contain electrical components. The electrical components can be similar to or the same as electrical components 430 (FIG. 4), 530 (FIG. 5), and/or 630 (FIG. 6). As examples, the electrical components can comprise pixels and/or sensors. In the same or other embodiments the flexible strips can comprise circuitry used for purposes other than displaying an image or detecting a foreign substance with sensors. In the same or other embodiments, the flexible strips can include shift registers. In some examples, a shift register is a CMOS shift register. In yet other embodiments, the rows of fibers can comprise textile threads. The textile threads can be similar to or the same as textile threads 420 (FIG. 4), 520 (FIG. 5), and/or 620 (FIG. 6).

Next, method 700 continues with a procedure 720 of providing columns of fibers. The fibers can be similar to or the same as fibers 310 (FIGS. 3-6). The columns of fibers can be similar to or the same as rows 312 (FIG. 3), 412 (FIG. 4), 512 (FIG. 5), and/or 612 (FIG. 6).

In some embodiments, the columns of fibers of procedure 720 comprise flexible strips. The flexible strips can be the same as or similar to flexible strips 425 (FIG. 4), 525 (FIG. 5), and/or 625 (FIG. 6). In some embodiments, the flexible strips contain electrical components. The electrical components can be similar to or the same as electrical components 430 (FIG. 4), 530 (FIG. 5), and/or 630 (FIG. 6). As examples, the electrical components can comprise pixels and/or sensors. In the same or other embodiments, the flexible strips can comprise circuitry used for purposes other than displaying an image or detecting a foreign substance with sensors. In the same or other embodiments, the flexible strips can include shift registers. In some examples, a shift register is a CMOS shift register. In yet other embodiments, the columns of fibers can comprise textile threads. The textile threads can be similar to or the same as textile threads 420 (FIG. 4), 520 (FIG. 5), or 620 (FIG. 6).

In some embodiments, only one of the rows of procedure 710 or the columns of procedure 720 contain flexible strips, while the other contains textile threads. For example, if the rows contain flexible strips, the columns will contain textile threads. Similarly, if the rows contain textile threads, the columns will contain flexible strips. In other embodiments, both the rows and columns can contain flexible strips. In yet other embodiments, the rows and/or the columns can contain both flexible strips and textile threads.

It should be noted that although method 700 contains procedures 710 and 720, the order of those two procedures can be altered. For example, the columns of fibers may be provided before the rows of fibers. In another example, the rows of fibers and the columns of fibers can be provided at the same time.

After procedure 720, method 700 continues with a procedure 730 of interweaving the rows and the columns of the fibers. In one embodiment, the rows and the columns of the fibers are woven together in an arrangement that is similar to or the same as the arrangements in FIGS. 3-6 and described above. In other embodiments, the rows and the columns of the fibers are woven together using any technique used to create textile fabrics.

After procedure 730, method 700 can be complete. However, method 700 can include additional procedures. For example, after procedure 730, method 700 can include a procedure of finishing the flexible device. The procedure of finishing the flexible device can include fabricating the flexible device into a garment that can be worn. As an example, the flexible device can be fabricated in the form of a shirt, sweater, vest, pants, shorts, or any other similar garment.

In addition, method 700 can include a procedure of providing additional components. For examples, the additional components can include a battery and/or a control unit. The battery and control unit can be the same as or similar to the battery and control unit described with respect to FIG. 4 above.

Furthermore, method 700 can include a procedure of providing at least one image to the flexible device. As an example, the flexible device can be connected to a control unit (such as a control unit provided in another procedure, or a control unit separate from the flexible device.) The control unit will instruct the flexible strips to display certain patterns at their respective pixels. In one example, all the data for a first flexible strip in a first row will be pushed to each of the pixels in that flexible strip. Then the data for a second flexible strip in a second row will be pushed to each of the pixels in that flexible strip. This procedure will happen for each flexible strip that is arranged in a row. Then the data will be pushed to each of the flexible strips arranged in a column, until each pixel in each flexible strip has received its data. In other examples, the columns are sent data before the rows. In yet other examples, the data is pushed to the columns and the rows in no particular pattern. If a new image is to be displayed, or if video is to be displayed, this procedure can be repeated.

Although the invention has been described with reference to specific embodiments, it will be understood by those skilled in the art that various changes can be made without departing from the spirit or scope of the invention. Accordingly, the disclosure of embodiments is intended to be illustrative of the scope of the invention and is not intended to be limiting. It is intended that the scope of the invention shall be limited only to the extent required by the appended claims. To one of ordinary skill in the art, it will be readily apparent that the invention discussed herein may be implemented in a variety of embodiments, and that the foregoing discussion of certain of these embodiments does not necessarily represent a complete description of all possible embodiments. Rather, the detailed description of the drawings, and the drawings themselves, disclose at least one preferred embodiment, and may disclose alternative embodiments.

All elements claimed in any particular claim are essential to the embodiment claimed in that particular claim. Consequently, replacement of one or more claimed elements constitutes reconstruction and not repair. Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A flexible device, comprising:
flexible strips;
wherein:
the flexible strips comprise:
electrical components; and
at least one shift register.

2. The flexible device of claim 1, wherein:
the electrical components comprise at least one pixel.

3. The flexible device of claim 1, wherein:
the electrical components comprise at least one sensor.

4. The flexible device of claim 1, wherein:
the at least one shift register comprises at least one CMOS shift register.

5. The flexible device of claim 1, further comprising:
a battery.

6. The flexible device of claim 1, further comprising:
a control unit.

7. The flexible device of claim 6, wherein:
the control unit comprises a microcontroller.

8. The flexible device of claim 6, wherein:
the control unit comprises a central processing unit.

9. The flexible device of claim 1, further comprising:
textile threads.

10. The flexible device of claim 9, wherein:
the flexible strips are arranged in rows;
the textile threads are arranged in columns; and
the flexible strips are interwoven with the textile threads.

11. The flexible device of claim 9, wherein:
the flexible strips are arranged in columns;
the textile threads are arranged in rows; and
the flexible strips are interwoven with the textile threads.

12. The flexible device of claim 1, wherein:
the flexible strips are arranged in rows and columns; and
the flexible strips arranged in the rows are interwoven with the flexible strips arranged in the columns.

13. A flexible device, comprising:
fibers arranged in rows and columns;
wherein:
the rows of fibers are interwoven with the columns of fibers;
at least a portion of the fibers comprise flexible strips;
each of the flexible strips comprises at least one electrical component; and
the rows of fibers are electrically decoupled to the columns of fibers.

14. The flexible device of claim 13, wherein:
the flexible strips comprise at least one shift register.

15. The flexible device of claim 13, wherein:
the flexible strips comprise at least one flexible CMOS shift register.

16. The flexible device of claim 13, wherein:
the at least one electrical component comprises at least one pixel.

17. The flexible device of claim 13, wherein:
the at least one electrical component comprises at least one sensor.

18. The flexible device of claim 13, wherein:
at least a portion of the fibers comprise textile threads.

19. The flexible device of claim 18, wherein:
the rows of fibers comprise the flexible strips; and
the columns of fibers comprise the textile threads.

20. The flexible device of claim 18, wherein:
the columns of fibers comprise the flexible strips; and
the rows of fibers comprise the textile threads.

21. The flexible device of claim 13, wherein:
the rows of fibers comprise a first portion of the flexible strips; and
the columns of fibers comprise a second portion of the flexible strips.

22. A method of providing a flexible device, comprising:
providing fibers to comprise:
one or more rows of fibers; and
one or more columns of fibers;
and
interweaving the one or more rows of fibers with the one or more columns of fibers;
wherein:
at least a portion of the fibers comprise flexible strips; and
the flexible strips comprise one or more electrical components.

23. The method of claim 22, wherein:
the one or more electrical components comprise at least one pixel.

24. The method of claim 22, wherein:
the one or more electrical components comprise at least one sensor.

25. The method of claim 22, wherein:
providing the fibers comprises:
providing at least a portion of the one or more rows of fibers to comprise the flexible strips and the one or more electrical components; and
providing at least a portion of the one or more columns of fibers to comprise textile threads.

26. The method of claim 22, wherein:
providing the fibers comprises:
providing at least a portion of the one or more columns of fibers to comprise the flexible strips and the one or more electrical components; and
providing at least a portion of the one or more rows of fibers to comprise textile threads.

27. The method of claim 22, wherein:
providing the fibers comprises:
providing at least a portion of the one or more columns of fibers to comprise a first portion of the flexible strips and a first portion of the one or more electrical components; and
providing at least a portion of the one or more rows of fibers to comprise a second portion of the flexible strips and a second portion of the one or more electrical components.
